(19) United States
(12) Patent Application Publication
(10) Pub. No.: US 2006/0071840 A1
(43) Pub. Date: Apr. 6, 2006

(54) Circuit structure and circuit substrate for modifying charcteristic impedance by using different reference planes

(76) Inventors: Yu-Chiang Cheng, Taipei City (TW); Kuo-Ming Chuang, Sinjhuang City (TW)

Correspondence Address: J C PATENTS, INC., 4 VENTURE, SUITE 250, IRVINE, CA, 92618, US

(21) Appl. No.: 11/149,795

(22) Filed: Jun. 9, 2005

(30) Foreign Application Priority Data
Sep. 15, 2004 (TW) 93127823

(51) Int. Cl. H03M 1/12

(52) U.S. Cl. 341/155

(57) ABSTRACT

A circuit structure for modifying characteristic impedance by using different reference planes is provided. The structure comprises an analog signal line, a digital signal line, a reference plane for analog signals and a reference plane for digital signals. Wherein, the line width of the analog signal line is the same as that of the digital signal line. In addition, the distance between the analog signal line and the analog signal reference plane is longer than the distance between the digital signal line and the digital signal reference plane. Accordingly, the characteristic impedance mismatch during signal transmission can be solved and the quality of signal transmission can be improved.

### CROSS-REFERENCE TO RELATED APPLICATION

This application claims the priority benefit of Taiwan application serial no. 93127823, filed on Sep. 15, 2004. All disclosure of the Taiwan application is incorporated herein by reference.

### BACKGROUND OF THE INVENTION

1. Field of the Invention

The present invention relates to a circuit substrate, and more particularly, to a circuit structure and a circuit substrate for modifying characteristic impedance by using different reference planes.

2. Description of the Related Art

Motherboards are an essential part of computers, controlling signal and data transmission, such as digital signals or analog signals, between devices. Generally speaking, signals transmitted in or between computers are presented by separate-type digital signals, such as signals with a high-voltage or low-voltage level, rather than the continuously varying signals as analog signals. Therefore, when analog signals are inputted from peripheral devices to a processor, an analog-digital transformation process is performed to transfer the analog signals into digital signals to complete signal transmission.

Additionally, in circuit layouts, characteristic impedance for analog signals should be higher than that for digital signals. However, when analog signals and digital signals coexist in the same motherboard, analog signals and digital signals of the same plane share the same reference plane, such as a power plane or a ground plane as a voltage reference for transmitting the analog and digital signals. This method, however, has the following problems. The high characteristic impedance for the digital signals would result in impedance mismatch. In consequence, electrical-magnetic interference (EMI) becomes more serious.

The conventional method for resolving the impedance mismatch is by increasing the line width of the digital signal line or reducing the line width of the analog signal line to modulate the impedance mismatch. However, since the digital signal line and the analog signal line are on the same plane, if the line width of the digital signal line is increased, the original line spaces of the layout would change, and the density of the layout would decline. Additionally, for the line width of the analog line to be reduced, more sophisticated equipment is required for the process, and the manufacturing costs of motherboards will be higher.

### SUMMARY OF THE INVENTION

Accordingly, the present invention is directed to a circuit structure for modifying characteristic impedance by using different reference planes. The circuit structure is used to modify desired characteristic impedance of digital and analog signals to achieve characteristic impedance match.

In order to achieve the object described above, the present invention provides a circuit structure for modifying characteristic impedance by using different reference planes, the circuit structure comprising an analog signal line, a digital signal line, an analog signal reference plane, and a digital signal reference plane. Wherein, the analog signal line has a same line width as the digital signal line. Besides, the analog signal reference plane is separated from the analog signal by a first distance. The digital signal reference plane is separated from the digital signal by a second distance, and the second distance is shorter than the first distance.

In order to achieve the object described above, the present invention provides a circuit substrate for modifying characteristic impedance by using different reference planes, the circuit substrate comprising an analog signal line, a digital signal line, an analog signal reference plane, a digital signal reference plane, and a plurality of dielectric layers. Wherein, the digital signal line has a same line width as the analog signal line. Besides, the analog signal reference plane is separated from the analog signal line by a first distance. The digital signal reference plane is separated from the digital signal line by a second distance, and the second distance is shorter than the first distance. Additionally, these dielectric layers are disposed between the analog signal line and the analog signal reference plane, and between the digital signal line and digital signal reference plane, respectively.

According to an embodiment of the present invention, the analog signal line and the digital signal line described above, for example, are on the same plane or on different planes.

According to an embodiment of the present invention, the analog signal reference plane is, for example, a power plane or a ground plane. Additionally, the digital signal reference plane is, for example, a power plane or a ground plane.

The digital signal line and the analog signal line of the present invention use different reference planes as voltage references while digital signals and analog signals are transmitted. Accordingly, the impedance mismatch resulting from the same reference plane used by the digital and the analog signals of the same plane can be solved, and quality of signal transmission can be improved.

The above and other features of the present invention will be better understood from the following detailed description of the embodiments of the invention that is provided in conjunction with the accompanying drawings.

### BRIEF DESCRIPTION OF THE DRAWINGS

FIG. 1 is a schematic cross-sectional view showing a circuit structure for modifying characteristic impedance by using different reference planes according to an embodiment of the present invention.

FIG. 2 is a schematic cross-sectional view showing a circuit structure for modifying characteristic impedance by using different reference planes according to another embodiment of the present invention.

FIG. 3 is a schematic cross-sectional view showing a circuit structure for modifying characteristic impedance by using different reference planes according to yet another embodiment of the present invention.

### DESCRIPTION OF SOME EMBODIMENTS

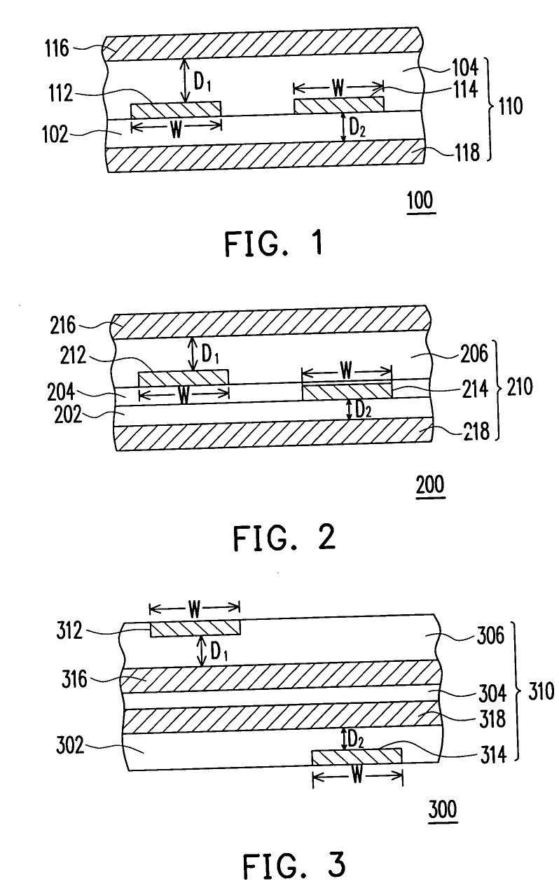

FIG. 1 is a schematic cross-sectional view showing a circuit structure for modifying characteristic impedance by using different reference planes according to an embodiment of the present invention. The following is a description of a circuit substrate 100 with multiple dielectric layers. The dielectric layers 102 and 104 of the circuit substrate 100 are stacked in the circuit structure 110 such that the signal lines 112 and 114 are separated from the reference planes 116 and 118 by proper distances, respectively. In this embodiment, the circuit structure 110 comprises an analog signal line 112, a digital signal line 114, an analog signal reference plane 116 and a digital signal reference plane 118. Wherein, the analog signal line 112 transceives, for example, continuously varying signals inputted from peripheral devices (not shown), or those generated from the digital/analog transformation process. Additionally, the digital signal line 114 transceives, for example, separated-type signals outputted from a processor (not shown), or those generated from the analog/digital transformation process.

Note that the characteristic impedance for the analog signal should be higher than that for the digital signal in circuit layout. In this embodiment, different reference planes are used to modify the characteristic impedance for the analog and digital signals. Wherein, the analog signal line 112, for example, is on the same plane with the digital signal line 114. Moreover, both have the same line width so costs for manufacturing equipment are reduced. The analog signal reference plane 116 and the digital signal reference plane 118, for example, are at two opposing sides parallel to the analog signal line 112 and the digital signal line 114. The analog signal line 112 is separated from the analog signal reference plane 116 by a first distance D1, and the digital signal line 114 is separated from the digital signal reference plane 118 by a second distance D2.

The equivalent formula of the characteristic impedance Z is given by:

$$Z = ( \frac{60}{\sqrt{E}} ) ln [ \frac{4 D}{0.67 π W ( 0.8 + T / W )} ]$$

When the line width W and the cross-sectional area are constant, if the distance D between a signal line and a reference plane is longer, the characteristic impedance Z of the signal line accordingly increases. According to the relation described above, in this embodiment, the distance between the analog signal line 112 and the analog signal reference plane 116, i.e. the first distance D1, is increased, or the distance between the digital signal line 114 and the digital signal reference plane 118, i.e. the second distance D2, is reduced, such that the first distance D1 is longer than the second distance D2 to modify the characteristic impedance for the analog signals and digital signals. The quality of the signal transmission can thus be improved.

The characteristic impedance Z obtained according to the method described above enables the characteristic impedance for the analog signal to be higher than the characteristic impedance for the digital signal. Accordingly, the high characteristic impedance resulting from the same reference plane used by the digital signals and analog signals of the same plane can be avoided. Without having to change the line width, the present invention is able to lower costs, provide simple circuit layouts and reduce electrical-magnetic interference (EMI).

FIG. 2 is a schematic cross-sectional view showing a circuit structure for modifying characteristic impedance by using different reference planes according to another embodiment of the present invention. The following is a description of a circuit substrate 200 with multiple dielectric layers. The dielectric layers 202, 204 and 206 of the circuit substrate 200 are stacked in the circuit structure 210 such that the signal lines 212 and 214 are separated, or the signal lines 212 and 214 are separated from the reference planes 216 and 218, by proper distances. In this embodiment, the circuit structure 210 comprises an analog signal line 212, a digital signal line 214, an analog signal reference plane 216 and a digital signal reference plane 218. Compared with the last embodiment, the analog signal line 212 and the digital signal line 214 in this embodiment are not on the same plane. The analog signal line 212 and the digital signal line 214 are separated, for example, by a dielectric layer 204 with a proper distance.

According to the formula described above, when the line width W and the cross-sectional area are constant, if the distance between the analog signal line 212 and the analog reference plane 216 is longer, the characteristic impedance Z of the analog signal line 212 accordingly increases. According to the relation described above, in this embodiment, the distance between the analog signal line 212 and the analog signal reference plane 216, i.e. the first distance D1, is increased, or the distance between the digital signal line 214 and the digital signal reference plane 218, i.e. the second distance D2, is reduced such that the first distance D1 is longer than the second distance D2 to modify the characteristic impedance for the analog signal and digital signal and improve the quality of the signal transmission. Without having to change the line width of the analog line 212 and the digital line 214, the present invention is able to reduce electrical-magnetic interference.

FIG. 3 is a schematic cross-sectional view showing a circuit structure for modifying characteristic impedance by using different reference planes according to yet another embodiment of the present invention. The following is a description of a circuit substrate 300 with multiple dielectric layers. The dielectric layers 302, 304 and 306 of the circuit substrate 300 are stacked in the circuit structure 310 such that the signal lines 312 and 314 are separated from the reference planes 316 and 318, or the reference plane 316 is separated from reference plane 318, by proper distances. In this embodiment, the circuit structure 310 comprises an analog signal line 312, a digital signal line 314, an analog signal reference plane 316 and a digital signal reference plane 318. Compared with the previous two embodiments, the analog signal line 312 is above the analog signal reference plane 316 and the digital signal line 314 is under the digital signal reference plane 318. The analog signal reference plane 316 and the digital signal reference plane 318 are separated, for example, by a dielectric layer 304 with a proper distance.

According to the same formula described above, when the line width W and the cross-sectional area are constant, if the distance between the analog signal line 312 and the analog reference plane 316 is longer, the characteristic impedance Z of the analog signal line 312 accordingly increases. According to the relation described above, in this embodiment, the distance between the analog signal line 312 and the analog signal reference plane 316, i.e. the first distance D1, is increased, or the distance between the digital signal line 314 and the digital signal reference plane 318, i.e. the second distance D2, is reduced such that the first distance D1 is longer than the second distance D2 to modify the characteristic impedance for the analog signal and digital signal and improve the quality of the signal transmission. Without having to change the line widths of the analog signal line 312 and the digital signal line 314, the present invention is able to reduce electrical-magnetic interference.

According to these three embodiments, the digital signal line and the analog signal line of the present invention use different reference planes as voltage references for the transmission of digital signals and analog signals. Accordingly, the characteristic impedance mismatch resulting from the same reference plane used by the digital signal and the analog signal of the same plane can be solved. Without having to change the line width, the present invention is able to lower costs, provide simple circuit layouts and reduce electrical-magnetic interference.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A circuit structure for modifying characteristic impedance by using different reference planes, the circuit structure comprising:
an analog signal line;
a digital signal line having a same line width as the analog line;
an analog signal reference plane separated from the analog signal line by a first distance; and
a digital signal reference plane separated from the digital signal line by a second distance, the second distance being shorter than the first distance.

2. The circuit structure for modifying characteristic impedance by using different reference planes of claim 1, wherein the analog signal line and the digital signal line are on a same plane.

3. The circuit structure for modifying characteristic impedance by using different reference planes of claim 1, wherein the analog signal line and the digital signal line are on different planes.

4. The circuit structure for modifying characteristic impedance by using different reference planes of claim 1, wherein the analog signal reference plane is a power plane or a ground plane.

5. The circuit structure for modifying characteristic impedance by using different reference planes of claim 1, wherein the digital signal reference plane is a power plane or a ground plane.

6. A circuit substrate for modifying characteristic impedance by using different reference planes, the circuit substrate comprising:
an analog signal line;
a digital signal line having a same line width as the analog line;
an analog signal reference plane separated from the analog signal line by a first distance;
a digital signal reference plane separated from the digital signal line by a second distance, the second distance being shorter than the first distance;
a first dielectric layer disposed between the analog signal line and the analog signal reference plane; and
a second dielectric layer disposed between the digital signal line and the digital signal reference plane.

7. The circuit substrate for modifying characteristic impedance by using different reference planes of claim 6, wherein the analog signal line and the digital signal line are on a same plane.

8. The circuit substrate for modifying characteristic impedance by using different reference planes of claim 6, wherein the analog signal line and the digital signal line are on different planes.

9. The circuit substrate for modifying characteristic impedance by using different reference planes of claim 8, further comprising a third dielectric layer disposed between the analog signal line and the digital signal line.

10. The circuit substrate for modifying characteristic impedance by using different reference planes of claim 8, further comprising a third dielectric layer disposed between the analog signal reference plane and the digital signal reference plane.

11. The circuit substrate for modifying characteristic impedance by using different reference planes of claim 6, wherein the analog signal reference plane is a power plane or a ground plane.

12. The circuit substrate for modifying characteristic impedance by using different reference planes of claim 6, wherein the digital signal reference plane is a power plane or a ground plane.
